(19) United States
(12) Patent Application Publication
(10) Pub. No.: US 2026/0262143 A1
(43) Pub. Date: Sep. 3, 2026

(54) MICROWAVE OVEN

(71) Applicant: ELECTROLUX APPLIANCES AKTIEBOLAG, Stockholm (SE)

(72) Inventors: Trevor SPECHT, Rothenburg ob der Tauber (DE); Dmytro SOKOVETS, Rothenburg ob der Tauber (DE); Diego FLORES GALINDO, Forli (DE)

(21) Appl. No.: 19/163,503

(22) PCT Filed: Mar. 7, 2024
(86) PCT No.: PCT/EP2024/056017

§ 371 Date: Sep. 9, 2025

(30) Foreign Application Priority Data
Apr. 5, 2023 (EP) 23166861.7

(51) Int. Cl. H05B 6/64; H05K 7/20

(52) U.S. Cl. CPC H05B 6/642; H05B 6/6402; H05K 7/20145; H05K 7/20909

(57) ABSTRACT

A microwave oven includes a cavity casing defining an oven cavity for treating food, the cavity casing including a frontal opening that can be closed by a door; electrical components including at least an inverter and a magnetron; an oven housing enclosing the cavity casing and a component chamber above the oven cavity, wherein the electrical components are aligned; and a cooling fan assembly. The cooling fan assembly includes a fan configured to ventilate the oven cavity and/or door and to force cooling air through the inverter and magnetron. Further, the cooling fan assembly includes an air duct having a main channel connected to the fan and two air duct branches that branch from the main channel, wherein a first air duct branch is in fluid connection with the inverter and a second air duct branch is in fluid connection with the magnetron.

Modern cooking ovens often comprise different functions, besides a standard heating function for example a microwave heating function, a steam cooking function and/or a pyrolytic cleaning function. For each function special components are required. Further, most of said components must be cooled down.

For example, a magnetron for the microwave heating function requires an active cooling with a specific flow rate. Usually, a cooling fan blows an air stream directly or via a duct to the magnetron. In case of a cooking oven with pyrolytic cleaning function, the housing, the oven door and the electronic circuits are usually kept cool by a double-channel cooling system for safety and functionality reasons. For example, said double-channel cooling system is driven by a double-inlet centrifugal fan. The one inlet is connected to a suction channel extending to the oven door and cavity exhaust, wherein sucked air keeps the oven door cool on the one hand and evacuates moist air from the cavity on the other hand. The other inlet is open, wherein air from a space between a cavity casing and a housing is sucked for cooling the housing and electronic elements. The outlet of the centrifugal fan is connected to a blowing channel through which the air is blown out of the cooling system.

A cooking oven with microwave heating function and pyrolytic cleaning function comprises usually two cooling fans. The one cooling fan is provided for cooling the magnetron, while the other cooling fan drives the double-channel cooling system for cooling the oven door, the housing and the electronic elements (s. above). However, this concept is complex and expensive, since two cooling fans are required.

It is an object of the present invention to improve cooling of a microwave oven.

That object is solved by a microwave oven with the features of claim 1. Additional expedient and/or per se inventive embodiments are described in the dependent claims and the following specification.

The microwave oven according to the invention comprises a cavity casing defining an oven cavity for treating food and electrical components comprising at least an inverter and a magnetron. The cavity casing comprises besides a top and a bottom wall as well as two opposing sidewalls and a rear wall a frontal opening that can be closed by a door. The microwave oven further comprises an oven housing enclosing the cavity casing and a component chamber positioned above the oven cavity wherein the electrical components are aligned. Especially, the electrical components are aligned at least partially on the cavity casing or an intermediate (or inner) carrier element (that serves e.g. for holding several components and/or the oven housing) that may be aligned on the cavity casing (and, thus, within the component chamber). Also, the microwave oven comprises a cooling fan assembly. That cooling fan assembly comprises only one fan configured to ventilate the oven cavity (and/or an oven door) and to force cooling air through the inverter and the magnetron. Further, the cooling fan assembly comprises an air duct that branches from a main channel connected to the fan into two air duct branches. A first one of such air duct branches is in fluid connection with the inverter and a second one of such air duct branches is in fluid connection with the magnetron.

In other words, the invention integrates the ventilation of the cavity and/or the oven door with the cooling of the magnetron and the inverter. Additionally, the branching air duct for connecting the inverter and magnetron to the fan enables a better cooling efficiency than only ventilating a space between the cavity casing and the oven housing in which the inverter and magnetron are aligned.

According to a preferred embodiment, the air duct is in fluid connection with a suction side (or inlet side) of the fan.

According to an expedient embodiment, the fan is configured as a double inlet centrifugal fan. For that, the fan preferably comprises a fan wheel with a double-sided suction functionality with respect to the opposing axial sides of the fan wheel. Especially, a first inlet of the fan is aligned at a first axial side of the fan (especially of the fan wheel) and a second inlet of the fan is aligned at a second axial side of the fan. Preferably, both axial sides of the fan, especially the fan wheel, are separated by a parting wall of the fan wheel, whereupon respective fan blades are aligned on each axial side. Such design makes it possible to use different blade shapes for each axial side so that each side may have different suction behavior.

According to a preferred embodiment, the first inlet of the fan is in fluid connection with the oven cavity and the second inlet is in fluid connection with at least the inverter and the magnetron, especially by means of the air duct. According to a preferred variant, the first and second inlets and the respective ducts leading to them are fluidly separated, especially such that respective air streams within the ducts leading towards the fan would not be mixed up with each other.

According to an expedient embodiment, a fan outlet of the fan is in fluid connection with an outlet channel that in turn is connected to a front side of the oven housing. Here, that outlet channel is connected to the outside and, especially, to an oven door cooling channel.

According to a preferred embodiment, the air duct is of a half or partial shell shape. That half or partial shell in combination with the cavity casing or the inner carrier element forms a closed cross section of the first and second air duct branches. That makes installation quite easy since elements to be cooled would not have to be installed within a pipe-like closed air channel.

According to a preferred embodiment, the inverter and/or the magnetron is positioned within the first or the second air duct branch, respectively. Such alignment within the respective air duct branch enables an improved individual cooling of the inverter and/or the magnetron, respectively.

According to a preferred further development of the aforementioned embodiment, a shape of the cross section of the first and/or the second air duct branch is in parts adapted to the (especially outer) shape of the inverter or of the magnetron, respectively. Especially, the shape of the cross section of the respective air duct branch copies the respective cross section of the inverter or the magnetron. I.e., the shape of the cross section of the first and/or the second air duct branch follows the shape (especially the outer shape) of the inverter or of the magnetron at least partially.

According to an expedient further development, the respective first or second air duct branch of the air duct is (additionally to the adapted cross section) configured to follow the inverter or the magnetron in sections (or parts) along an air flow path. I.e., the respective air duct branch (especially seen in its longitudinal section) is preferably conformed to the inverter or magnetron, in distinct sections. Especially, the respective air duct branch has a clearance of about 1, 5 to 4 mm, especially of 2 to 3 mm, between a component of the inverter or of the magnetron and a channel outer wall. This enables for maintaining an airflow at a higher velocity along the respective component's surface being cooled compared to e.g. a rectangular air duct branch that is not conformed to the inverter or magnetron.

According to an expedient embodiment, the air duct comprises a number of air blocking or air directing ribs that protrude into the air flow path. Preferably, these ribs are aligned obliquely or perpendicular to a main flow direction within the respective air duct branch. These ribs serve for blocking an air flow within a distinct area (or region), especially within an area that does not require active cooling. Additionally or alternatively, these ribs serve for directing air flow to another area, especially an area that requires cooling.

According to a further expedient embodiment, especially wherein the magnetron is not aligned within the second air duct branch, a cross section of the second air duct branch is narrowed with respect to the cross section of the magnetron. Preferably, the cross section of the second air duct branch is narrowed with respect to the cross section of a cooling structure part of the magnetron. Usually, a magnetron is an assembly comprising also a cooling structure, preferably cooling fins, that makes up for only a part of the cross section (or geometrical “food print”) of the magnetron. By narrowing the air duct branch, the air flow through the magnetron may be focused to the cooling structure, making cooling more efficient.

According to a preferred embodiment, the first and the second air duct branch of the air duct are fluidly connected (directly or indirectly) to respective first and second vent openings within the oven housing. These first and second vent openings are preferably positioned within a rear sidewall and (especially longitudinal) sidewalls of the oven housing and these sidewalls are aligned obliquely or opposite to each other. For example, the first air duct branch is directly connected to (or at least ends at) a backwards facing (i. e. the rear) sidewall within an area wherein at least a group of the first vent openings is aligned. The second air duct branch may end within the room between the cavity casing and the oven housing such that other vent openings (i.e. the second ones) are connected indirectly with the second air duct branch. In that case, the second air duct branch may be used also to cool other electrical components that are aligned within that room.

Preferably, the first and the second air duct branches of the air duct open into the direction of at least some of the first or second vent openings, respectively. That means that the respective air duct branch is directed with its longitudinal axis into the direction of the first or second vent openings, respectively.

According to an expedient variant, the electrical (or electronic) components comprise at least a main printed circuit board (“main PCB”) which is mounted within an open flow path (i.e., the room between the cavity casing and the oven housing) between one of the first and second vent openings and the respective first or second air duct branch. Additionally, the electrical or electronic components may also comprise a user interface electronics that is mounted above the oven door cutout. According to a preferred embodiment, the fan, especially the fan wheel, is mounted with its rotation axis substantially normal to a top wall of the cavity casing or the aforementioned inner carrier element. Substantially normal is preferably understood as 90+/−about 10 degrees. Due to that alignment, short air flow path lengths or at least air flow paths with little rerouting may be accomplished.

According to an expedient embodiment, the first inlet of the fan is additionally in fluid connection with an oven door for cooling that oven door. Especially, the fluid connection is realized by means of a respective air duct.

The conjunction “and/or” is to be understood here and in the following in particular in such a way that the features linked by means of this conjunction may be realized both together as well as alternatives to each other.

An embodiment of the invention described before will be described by means of a drawing. Therein show:

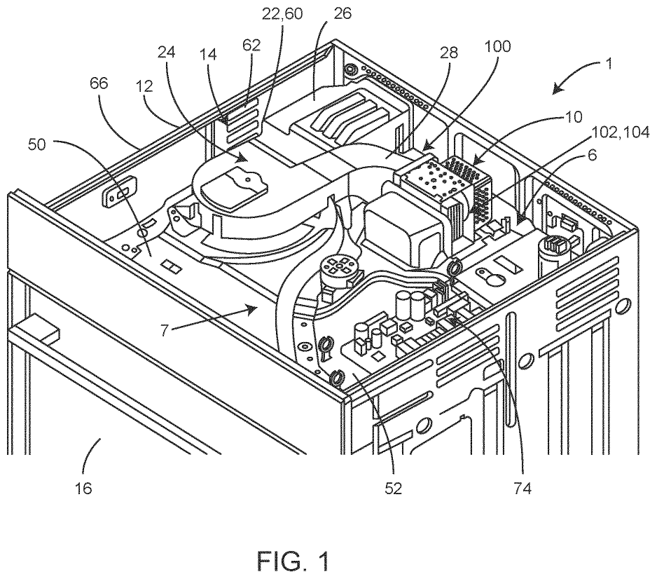

FIG. 1 in a partly translucent and cut open perspective view a microwave oven,

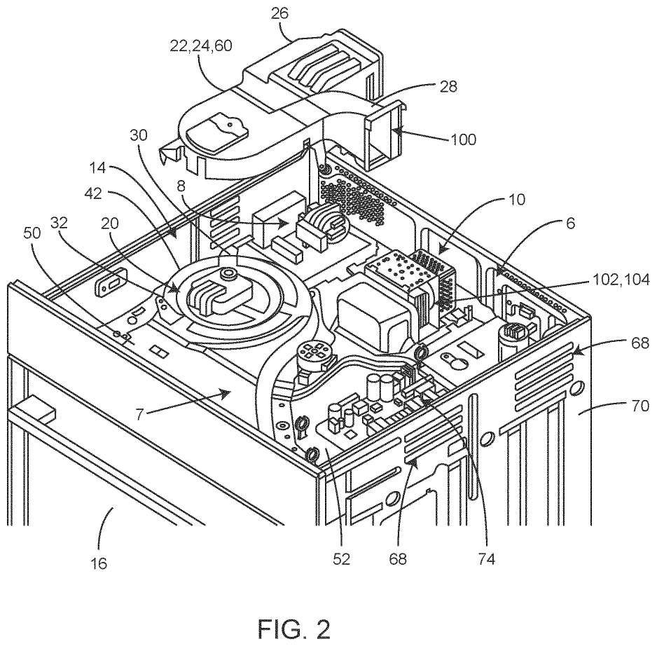

FIG. 2 in a view according FIG. 1 the microwave oven in a partly exploded view,

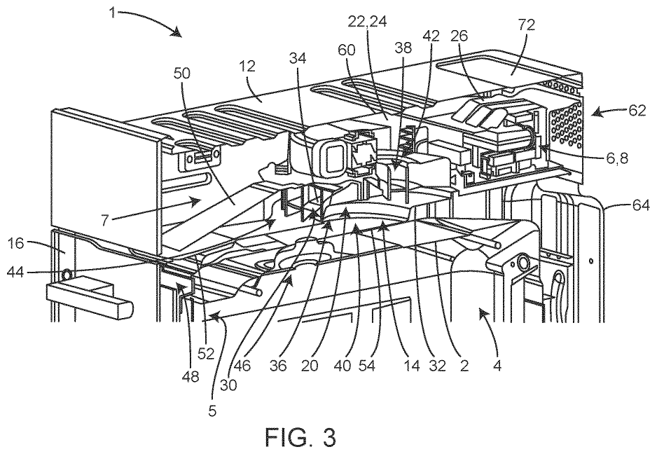

FIG. 3 in a partly cut view the microwave oven,

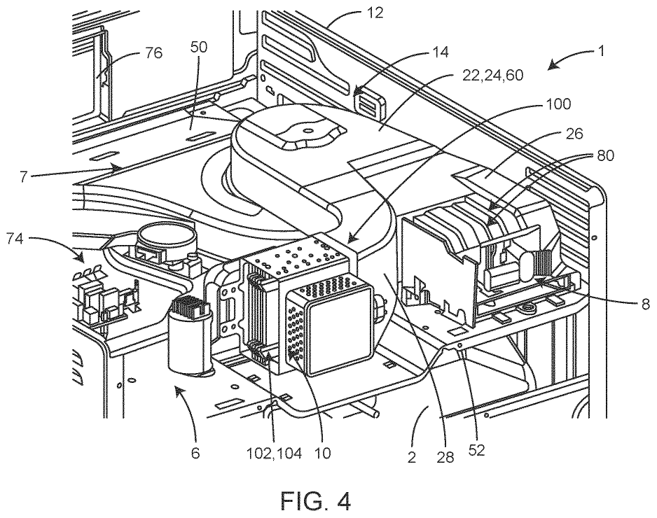

FIG. 4 in a detailed view a cooling fan assembly of the microwave oven,

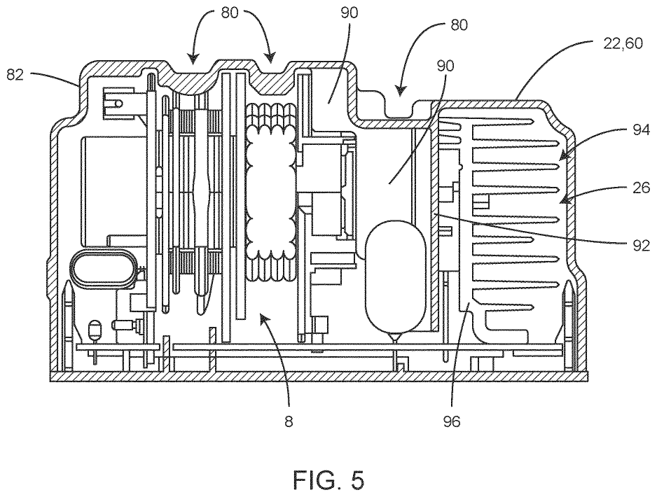

FIG. 5 in a cross-sectional view the cooling fan assembly,

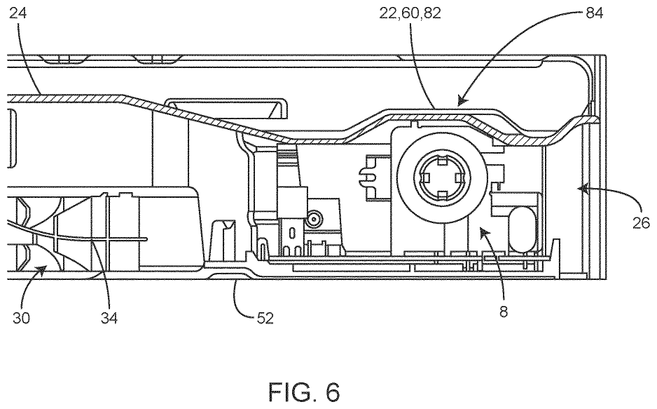

FIG. 6 in a longitudinally sectional view the cooling fan assembly, and

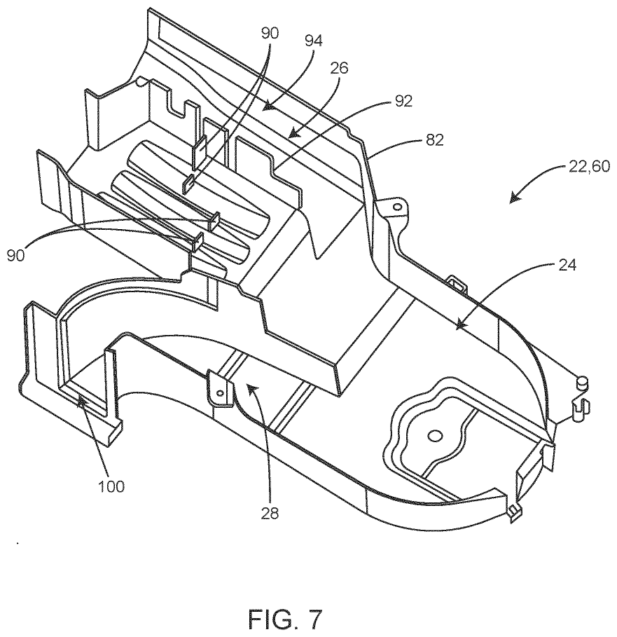

FIG. 7 in a schematic perspective view an air duct of the cooling fan assembly.

Corresponding parts are always given the same reference signs in all figures.

FIG. 1 shows a microwave oven 1. The microwave oven 1 comprises a cavity casing 2 which in turn defines an oven cavity 4 having a frontal opening 5 (cf. FIG. 3). The microwave oven 1 further comprises electrical components 6 that in turn comprise at least an inverter 8 (cf. FIG. 2) and a magnetron 10. The microwave oven 1 also comprises an oven housing (short: “housing 12”) enclosing the cavity casing 2 and a component chamber 7 that is positioned above the cavity casing 2. The electrical components 6 are aligned within that component chamber 7. Further, the microwave oven 1 comprises a cooling fan assembly 14. That cooling fan assembly 14 is configured-according to the embodiment shown in the figures-to ventilate and cool the oven cavity 4, an oven door 16 (for closing the frontal opening 5) and the electrical components 6.

As shown in more detail in the following figures the cooling fan assembly 14 comprises only one fan 20 that is configured to ventilate the oven cavity 4 and to force cooling air through the inverter 8 and the magnetron 10, as well as to ventilate the oven door 16. The cooling fan assembly 14 comprises an air duct 22 that branches from a main channel 24 connected to the fan 20 into a first air duct branch 26 and a second air duct branch 28. The first air duct branch 26 is in fluid connection with the inverter 8 and the second channel 28 is in fluid connection with the magnetron 10.

As it can be seen in more detail from FIGS. 2 and 3 the fan 20 is designed as a double inlet centrifugal fan. I.e., the fan 20 comprises a fan wheel 30 and a fan wheel housing 32. The fan wheel 30 is configured with a parting wall 34 separating a first axial side 36 from a second axial side 38. The fan wheel housing 32 has a first inlet 40 corresponding with the first axial side 36 and a second inlet 42 corresponding with the second axial side 38 of the fan wheel 30. The fan wheel housing 32 also comprises an fan outlet 44, that is aligned in a direction radial to the fan wheel 30 (s. FIG. 3).

The first inlet 40 is in fluid connection with a ventilation opening 46 of the oven cavity 4. Also, the first inlet 40 is in fluid connection with a oven door ventilation duct 48 (cf. FIG. 3). Also, the fan outlet 44 is in fluid connection with the door ventilation duct 48, especially at other positions than the first inlet 40. For that, the fan outlet 44 is fluidly connected to an outlet channel 50 that leads to the oven door 16. Preferably, the outlet channel 50 is designed to blow air through a slit above the oven door 16 such that a Venturi effect enables a suction effect to the oven door ventilation duct 48 (not shown in detail).

The fan wheel housing 32 and the outlet channel 50 are realized in combination with an intermediate (or inner) carrier element (short: “carrier 52”; e.g. a plate or similar) that is mounted between the cavity casing 2 and the housing 12. The fan wheel housing 32 and the outlet channel 50 comprise respective half (or partial) shells that are mounted to the carrier 52 in order to form the complete fan wheel housing 32 as well as the outlet channel 50. Also, another shell part 54 is mounted to the carrier 52 to form a ventilation duct 56 fluidly connected to the oven door ventilation duct 48 and to the ventilation opening 46 of the cavity casing 2.

The second inlet 42 of the fan 20 is in fluid connection with the main channel 24 of the air duct 22. The air duct 22 also comprises a (half or partial) shell 60 (cf. FIG. 7) that is mounted to the carrier 52 and to the fan wheel housing 32 to form a closed cross section (cf. FIGS. 2 and 3). The part of the shell 60 that in the intended assembly state (cf. FIG. 1) forms the first air duct branch 26 covers the inverter 8. The part of the shell 60 forming the second air duct branch 28 ends in the intended assembly state at the magnetron 10 (s. FIGS. 1 and 4). Thus, during intended operation of the fan 20 air is forced, in fact sucked, through the inverter 8 and the magnetron 10 into the direction of the second inlet 42, thereby cooling the respective components of the inverter 8 and the magnetron 10, respectively.

The air enters through first vent openings 62 that are aligned in a rear sidewall 64 and a sidewall 66 of the housing 12 as well as through second vent openings 68 that are aligned in the opposite sidewall 70. The first air duct branch 26 ends adjacent to the rear sidewall 64 such that the most of the first vent opening 62 aligned in that part open into the second air duct branch 26. The second vent openings 68 open up into the room between the carrier 52 and a top wall 72 of the housing 12. In that room the electrical components 6 (also e.g., a main PCB 74 and a user interface 76) are aligned. The air within that room is mainly sucked by means of the second air duct branch 28 through the magnetron 10. In the intended operational state of the microwave oven 1 there is a ventilation gap between the oven door 16 as well as the sidewalls 66 and 70 and a furniture into which the microwave oven 1 is installed. Through that gap air may be sucked and enter through the first and second vent opening 62 and 68 (not shown in detail).

In order to improve cooling effect of the air within the first air duct branch 26 the respective part of the shell 60 has indentations 80 from its outside in order to reduce a distance between the channel outer wall (“shell wall 82”) in the region where the inverter 8 is placed. These indentations 80 are chosen such that the first air duct branch 26 conforms to the outer structure (shape) of the inverter 8 (cf. FIG. 5). However, these indentations 80 are also shaped in the direction of the air flow through the first air duct branch 26 to follow the shape of the inverter 8 (cf. FIG. 6) such that the outer surface of the shell wall 82 shows some kind of hump 84. The indentations 80 are formed such that the distance between the shell wall 82 and several of the components of the inverter 8 is about 2 to 3 mm. By that a higher air flow velocity may be reached around the respective components of the inverter 8 compared to a rectangular cross section of the first air duct branch 26.

Additionally, within the first air duct branch 26 some ribs are placed. There are blocking ribs 90 that serve for blocking air flow from areas (or regions) where no cooling or less cooling is needed. Also, there is an air direction rib 92 that separates a flow path 94 within the first air duct branch 26. In that flow path 94 a heatsink 96 of the inverter 8 is aligned.

Further, as it may be seen in FIGS. 2 and 4, the second air duct branch 28 comprises a connecting end 100 that has a narrower cross section than a cooling structure part 102 of the magnetron 10. That enables a focused air flow through the cooling structure part 102 and, thus, along cooling fins 104 aligned therein.

The subject matter of the invention is not limited to the embodiment described above. Rather, further embodiments of the invention can be derived by the skilled person from the above description.

### LIST OF REFERENCE SIGNS

1 microwave oven
2 cavity casing
5 frontal opening
4 cavity
6 electrical components
7 component chamber
8 inverter
10 magnetron
12 housing
14 cooling fan assembly
16 oven door
20 fan
22 air duct
24 main channel
26 first air duct branch
28 second air duct branch
30 fan wheel
32 fan wheel housing
34 parting wall
36 first axial side
38 second axial side
40 first inlet
42 second inlet
44 fan outlet
46 ventilation opening
48 oven door ventilation duct
50 outlet channel
52 carrier
54 shell part
56 ventilation duct
60 shell
62 first vent opening
64 rear sidewall
66 sidewall
68 second vent opening
70 sidewall
72 top wall
74 main PCB
76 user interface
80 indentation
82 shell wall
84 hump
90 blocking rib
92 direction rib
94 flow path
96 heatsink
100 connecting end
102 cooling structure part
104 cooling fins

1. A microwave oven comprising;
a cavity casing defining an oven cavity for treating food, the cavity casing comprising a frontal opening that can be closed by a door,
electrical components comprising at least an inverter and a magnetron,
an oven housing enclosing the cavity casing and a component chamber above the oven cavity wherein the electrical components are arranged within the component chamber, and
a cooling fan assembly, wherein the cooling fan assembly comprises:
a fan configured to ventilate the oven cavity and/or an oven door and to force cooling air through the inverter and the magnetron, and
an air duct comprising a main channel connected to the fan into and two air duct branches from the main duct, wherein a first one air duct branch of the two air duct branches-being is in fluid connection with the inverter, and a second es suchair duct branch of the two air duct branches is in fluid connection with the magnetron.

2. The microwave oven according to claim 1, wherein the air duct is in fluid connection with a suction side of the fan.

3. The microwave oven according to claim 2, wherein the fan is configured as a double inlet centrifugal fan type, and wherein a first inlet of the fan is aligned at a first axial side of the fan and a second inlet of the fan is aligned at a second axial side of the fan.

4.The microwave oven according to claim 2, wherein a first inlet of the fan is in fluid connection with the oven cavity, and a second inlet of the fan is in fluid connection with at least the inverter and the magnetron by means of the air duct.

5. The microwave oven according to on Aclaim 1, wherein a fan outlet of the fan is in fluid connection with an outlet channel connected to a front side of the oven housing.

6. The microwave oven according to claim 1, wherein the air duct comprises a half or partial shell shape that in combination with the cavity casing or an inner carrier element forms a closed cross section of the first and second air duct branches.

7. The microwave oven according to claim 1, wherein the inverter is positioned within the first air duct branch and/or the magnetron is positioned within the second air duct branch.

8. The microwave oven according to claim 7, wherein a shape of the first air duct branch is at lesst partially adapted to a shape of the inverter.

9. The microwave oven according to claim 8, wherein the first air duct branch-is configured to follow the inverter in sections along an air flow path with a clearance of about 1.5 to 4 mm, between a component of the inverter and a channel outer wall.

10. The microwave oven according to claim 9, wherein the air ductcomprises air blocking or air directing ribs that protrude into the air flow path, wherein the air blocking or air directing ribs serve for blocking an air flow within a distinct area, that does not require active cooling and/or direct air flow to an area that requires cooling.

11. The microwave oven according to claim 1, wherein a cross section of the second air duct branch is narrowed with respect to a cross section of the magnetron, particularly of a cooling structure part of the magnetron.

12. The microwave oven according to claim 1, wherein the first and the second air duct branche of the air duct are fluidly connected to respective first and second vent openings within the oven housing the first and second vent openings being positioned within a rear sidewall and sidewalls, of the oven housing aligned obliquely or opposite to each other.

13. The microwave oven according to claim 12, wherein the first and the second air duct branches of the air duct open into a direction of the first or second vent openings espectively.

14. The microwave oven according to claim 12, wherein the electrical components comprise at least a main printed circuit board that is mounted within an open flow path between one of the first and second vent openings and a respective of the first and second air duct branches.

15. The microwave oven according to claim 1, wherein a rotation axis of the fan is substantially normal to a top wall of the cavity casing or an inner carrier element.

16. A microwave oven comprising:
a cavity casing defining an oven cavity for treating food;
a component chamber above the oven cavity;
electrical components located within the component chamber, the electrical components comprising an inverter and a magnetron;
a fan configured to force cooling air through the inverter and the magnetron; and
an air duct comprising a main channel connected to the fan and two air duct branches that branch from the main duct, wherein a first air duct branch of the two air duct branches is in fluid connection with the inverter and a second air duct branch of the two air duct branches is in fluid connection with the magnetron.

17. The microwave oven according to claim 16, wherein the fan includes:
a first inlet in fluid connection with the oven cavity,
a second inlet in fluid connection with the air duct, and
a fan outlet in fluid connection with an outlet channel.

18. The microwave oven according to claim 16, wherein the inverter is positioned within the first air duct branch and/or the magnetron is positioned within the second air duct branch.

19. The microwave oven according to claim 16, wherein:
the first and the second air duct branches are fluidly connected to respective first and second vent openings within the oven housing, and
the electrical components further comprise a main printed circuit board that is mounted between one of the first and second vent openings and a respective one of the first and second air duct branches.

20. A microwave oven comprising:
a cavity casing defining an oven cavity for treating food, and a frontal opening for providing access to the oven cavity;
a door for selectively opening and closing the frontal opening;
a component chamber above the oven cavity;
an oven housing enclosing the cavity casing and the component chamber, the oven housing comprising first and second vent openings;
electrical components located within the component chamber, the electrical components comprising an inverter, a magnetron, and a main printed circuit board;
a fan configured ventilate the oven cavity and/or door and to force cooling air through or across the inverter, magnetron, and main printed circuit board, wherein the fan includes a first inlet, a second inlet, and a fan outlet, the first inlet being in fluid communication with the oven cavity and/or door; and
an air duct comprising a main channel connected to the second inlet of the fan, and two air duct branches that branch from the main duct, wherein a first air duct branch of the two air duct branches is in fluid connection with the inverter and a second air duct branch of the two air duct branches is in fluid connection with the magnetron,
wherein the first and the second air duct branches of the air duct are fluidly connected to the first and second vent openings of the oven housing, respectively.
